(19) United States
(12) Patent Application Publication
(10) Pub. No.: US 2015/0227829 A1
(43) Pub. Date: Aug. 13, 2015

(54) LAMINATES FOR SECURITY DOCUMENTS

(71) Applicants: David Finn, Tourmakeady County Mayo (IE); Alan Considine, Clarecastle (IE); Patrick Gerard Conneely, Carraroe (IE)

(72) Inventors: David Finn, Tourmakeady County Mayo (IE); Alan Considine, Clarecastle (IE); Patrick Gerard Conneely, Carraroe (IE)

(21) Appl. No.: 14/622,949

(22) Filed: Feb. 16, 2015

Related U.S. Application Data
(63) Continuation-in-part of application No. 14/062,846, filed on Oct. 24, 2013, now Pat. No. 8,955,759.
Application No. 14/062,846 is a continuation of application No. 12/545,825, filed on Aug. 22, 2009, now Pat. No. 8,608,080.
(60) Provisional application No. 61/230,710, filed on Aug. 2, 2009.
(60) Provisional application No. 61/145,971, filed on Jan. 21, 2009.
(60) Provisional application No. 61/092,766, filed on Aug. 29, 2008.
(60) Provisional application No. 61/235,012, filed on Aug. 19, 2009.

(51) Int. Cl. G06K 19/077; H01L 23/00

(52) U.S. Cl. CPC G06K 19/07752; G06K 19/07722; H01L 24/83; H01L 24/27; H01L 2224/8385; H01L 2924/1421

(57) ABSTRACT

Secure inlays for secure documents such as a passport comprising an inlay substrate may have laser-ablated recesses within which a chip module is installed. The inlay substrate may include two layers, and the antenna wire may be between the two layers. A moisture-curing polyurethane hot melt adhesive may be used to laminate a cover layer and the additional inlay substrate layers. The adhesive layer may be used (i) as a sealant, to protect the interconnections, (ii) as a fixing mechanism for the chip module, and (iii) as an adhesive for joining the two substrates (inlay and leadframe substrates) together. Method and apparatus are disclosed.

### CROSS-REFERENCE TO RELATED APPLICATIONS

This is a continuation-in-part of Ser. No. 14/062,846 filed 24 Oct. 2013 (U.S. Pat. No. 8,955,759, 17 Feb. 2015) which is a continuation of U.S. Ser. No. 12/545,825 filed 22 Aug. 2009 (U.S. Pat. No. 8,608,080, 17 Dec. 2013) which claims priority from

61/230,710 filed 2 Aug. 2009

61/145,971 filed 21 Jan. 2009

61/092,766 filed 29 Aug. 2008

61/235,012 filed 19 Aug. 2009

### TECHNICAL FIELD

The invention relates to “inlay substrates” used in the production of “inlays” for “security documents” such as electronic passports and electronic identification cards.

### BACKGROUND

A “security document” such as an electronic passport (ePassport) or an electronic identification (eID) card may comprise an “inlay substrate” (or “inlay laminate”) which is typically a sheet (or layer) of material such as Teslin™, with a Radio Frequency Identification (RFID) chip module and corresponding antenna mounted therein. An ePassport may have an additional “cover layer” (or “cover material”), such as PVC-coated paper, cloth or synthetic leather laminated (or joined) thereto. An eID card may have an additional upper “overlay layer” of anti-scratch, typically transparent material, with an adhesive backing laminated thereto, and an additional “bottom layer”, which may have a magnetic stripe.

In the main hereinafter, the inlay substrate (or inlay laminate) portion of security documents which are electronic passports (ePassport) are discussed. The inlay substrate, with transponder module and antenna incorporated therein may be referred to as a “secure inlay”.

Examples of Some Secure Documents

An electronic passport cover (or “e-cover”) generally comprises a hinged cover comprising a front panel (or portion) and a back panel (or portion), and an insert of several pages disposed within the e-cover. The “passport card” is an alternative to an ordinary US passport cover. Both the passport cover and passport card include a vicinity-read radio frequency identification (RFID) chip. The RFID chip in the passport card (eID card) is designed to be readable at a greater distance than that of the passport cover, and to prevent the RFID chip from being read when the passport card (eID card) is not being used, the passport card (eID card) typically comes with a sleeve designed to block the RFID chip from being read while the card is in the sleeve. See, for example, US 20070205953, incorporated by reference herein.

FIG. 1A shows an example of a security document which may an electronic “passport cover” (e-cover) comprising an inlay substrate (layer) and a cover layer (cover material). An RFID chip module (not shown) and corresponding antenna (not shown) may be mounted (disposed, embedded) in the inlay substrate. An insert having several pages (not shown) for presenting printed information and receiving visa (entry and exit) stamps may be mounted within the passport cover. Notice that the passport cover, cover layer and inlay substrate may be folded, resulting in a front cover panel (portion) and a back cover panel (portion) of the passport cover. The passport cover is shown partially open (partially closed). In use, when being examined, scanned or stamped by a border (Vama, Duoanes) official, the passport cover may be fully open. When the passport cover is closed, the cover layer is external to (surrounds) the inlay substrate. The passport cover, cover layer and inlay substrate are not shown to scale.

FIG. 1B shows an example of a security document which may be an identification (eID) card having an inlay substrate (layer), and additional layers comprising a top overlay layer and a bottom layer. An RFID chip module and corresponding antenna (not shown) may be mounted in the inlay substrate (middle layer). The additional top and bottom layers may be anti-scratch layers, and protect the inlay substrate in the middle from top and bottom. The eID card, inlay substrate layer and top and bottom layers are not shown to scale.

Examples of Some RFID Chip Modules

In the main hereinafter, the discussion may focus on RFID chip modules which are leadframe-type modules. However, some of the techniques for producing security documents discussed herein may also be applicable to epoxy glass modules (chip on FR4, wire bonded, glob topped).

FIG. 1C shows an example of an RFID chip module which is a “leadframe module” comprising:
a leadframe having a thickness of approximately 80 μm
an RFID chip disposed on and connected by wire bonds to the leadframe, having a thickness of approximately 80 μm
a mold mass disposed over the chip and wire bonds, having a thickness of approximately 240 μm
an antenna wire having end portions connected to “connection areas” of the leadframe, typically on a side of the leadframe opposite the RFID chip (as shown), but the end portions can also be connected to connection areas on the same side of the lead frame as the RFID chip.

The total thickness of the leadframe module may be 320 μm, such as for an inlay substrate having a thickness of approximately 356 μm. Generally, the chip module will be disposed in a recess in the inlay substrate so as to be concealed therein.

FIG. 1D shows an example of an RFID chip module which is an “epoxy glass module” comprising:
an interconnect substrate, such as FR4 (printed circuit board substrate material), having a thickness of approximately 100 μm (FR4 is 100 μm and the chip & glob top 160 μm=overall 260 μm)
an RFID chip, wire-bonded (alternatively flip-chip connected with solder bumps and underfiller, as illustrated) to the FR4 substrate, having a thickness of approximately 100 μm
a glob top epoxy disposed over the chip and connections, having a thickness with chip of approximately 160 μm
an antenna wire having ends connected to “connection pads”, typically on the same side of the FR4 substrate as the RFID chip, but can also be connected on the opposite side of the FR4 substrate as the chip.

The total thickness of the epoxy glass module may be 260 μm, such as for an inlay substrate having a thickness of approximately 365 μm. Generally, the chip module will be disposed in a recess in the inlay substrate so as to be concealed therein.

Generally speaking, epoxy glass modules are inherently somewhat more flexible than leadframe modules. This is a factor that may need to be taken into consideration when incorporating an RFID module into a secure document. And, whereas leadframe modules are typically rectangular, the mold part (glob top) of an epoxy glass module are typically round.

It should be understood that, although FIG. 1D shows a flip chip connection between the RFID chip and the FR4 substrate, the chip can be wire-bonded to the substrate (such as was shown in FIG. 1C, for the leadframe-type module.)

### SOME DEFINITIONS AND TERMINOLOGY

An “inlay” or “inlay laminate” may comprise an “inlay substrate” which is a planar sheet of plastic material, such as Teslin™. A “chip module” disposed in a “recess” in the inlay substrate. An antenna wire is mounted to the inlay substrate, such as be embedding (countersinking) within or adhesively attaching (sticking, placing) to a surface of the inlay substrate.

A chip module may include an RFID (radio frequency identification) chip and means such as a leadframe or an epoxy-glass (FR4) substrate for facilitating interconnecting the RFID chip with an antenna. Some RFID chips have integrated antennas, and do not require the means for interconnecting with and antenna. As used herein “chip” and “chip module” can encompass many configurations of a silicon die or a packaged chip.

The antenna is typically in the form of a flat coil of wire having a number (such as 4 or 5) of turns and two end portions which are connected to corresponding contact pads (contact areas, terminals) of the chip module. The antenna may be a dipole antenna having two wire segments with two inner ends, or any other antenna configuration suitable for connection to a chip or chip module in an inlay. The wire may include any elongate means for conveying or radiating signals, such as metallic wire (such as gold, aluminum, copper, silver), of any profile (such as round or rectangular), either bare, coated or color coated, as well as optical fibers.

The recess for receiving the chip module extends into the inlay substrate from a “top” surface thereof, and may be a “window” type recess extending completely through the inlay substrate to a “bottom” surface thereof, or the recess may be a “pocket” type recess extending only partially through the inlay substrate towards the bottom surface thereof.

The recess may have a “straight” profile—in other words, substantially constant cross-dimension through (or into) the inlay substrate. Or, the recess may have a “stepped” profile, including a larger cross-dimension at the top surface of the substrate than at (or towards) the bottom surface of the inlay substrate. The recess is generally sized and shaped to accommodate the size and shape of the chip module being disposed therein. The term “cavity” may be used interchangeably with “recess”.

A secure document, such as an electronic passport (e-passport) comprises an “inlay” (inlay substrate, plus chip module, plus antenna) and a “cover” layer (or substrate). The inlay plus cover constitute an “e-cover”. The “inlay” may be fully functional, but rarely would be used on its own, without additional, protective layers (such as the cover layer) laminated thereto.

The inlay substrate may comprise, for example, Teslin™, PVC, Polycarbonate (PC), polyethylene (PE) PET (doped PE), PETE (derivative of PE), and the like.

The cover layer may comprise, for example, PVC, coated offset board, with or without optical bleacher or acrylic coated cotton, supplied in web form or in sheets.

E-covers may be manufactured several at a time, such as “3up”, on an “inlay sheet” which may include several (a plurality of) distinct “transponder areas” (or “transponder sites”) on an “oversize” inlay substrate, for forming a plurality of e-covers. Each transponder site may comprise a chip module and antenna mounted to the inlay substrate. The chip module and antenna may be referred to as a “transponder”. A cover layer may be laminated (joined) thereto, then the individual e-covers may be separated from the inlay sheet.

An Inlay and Transponder of the Prior Art

FIGS. 1E and 1F illustrate an inlay sheet 100 having a plurality of transponder areas (or sites). A selected one of the transponder areas 102 is shown in detail. The vertical and horizontal dashed lines (in FIG. 1E) are intended to indicate that there may be additional transponder areas (and corresponding additional transponders) disposed to the left and right of, as well as above and below, the transponder area 102, on the inlay sheet 100. As best viewed in FIG. 1F, the inlay sheet 100 may be a multi-layer substrate 104 comprising one or more upper (top) layers 104a and one or more lower (bottom) layers 104b.

A recess 106 may be formed in (completely through) the upper layer 104a so that a transponder chip 108 may be disposed in the recess 106, and supported by the lower layer 104b. The transponder chip 108 is shown having two terminals 108a and 108b on a top surface thereof.

This inlay sheet 100 is representative of a credit card, using hot lamination to bond the material. The overall thickness of the inlay sheet (104a and 104b) is approximately 450 μm.
the thickness of a top overlay layer (not shown), approximately 50 μm
the thickness of the top layer(s) 104a, approximately 400 μm
depth of the recess 106, same as thickness of the top layer(s) 104a
thickness of the transponder chip 108, approximately 320 μm
thickness of the bottom layer(s) 104b, approximately 240 μm

Generally, the recess 106 is sized and shaped to accurately position the transponder chip 108, having side dimensions only slightly larger than the transponder chip 108 to allow the transponder chip 108 to be located within the recess 106. For example,
the transponder chip 108 may measure: 5.0×8.0 mm
the recess 106 may measure: 5.1×8.1 mm
the terminals 108a/b may measure: 5.0×1.45 mm
the wire (discussed below) may have a diameter between 60 and 112 μm

One millimeter (mm) equals one thousand (1000) micrometers (μm, “micron”).

In FIGS. 1E and 1F, the recess 106 may be illustrated with an exaggerated gap between its inside edges and the outside edges of the chip 108, for illustrative clarity. In reality, the gap may be only approximately 50 μm-100 μm (0.05 mm-0.1 mm)

In FIG. 1E the terminals 108a and 108b are shown reduced in size (narrower in width), for illustrative clarity. (From the dimensions given above, it is apparent that the terminals 108a and 108b can extend substantially the full width of the transponder chip 108.)

It should be understood that the transponder chip 108 is generally snugly received within the recess 106, with dimensions suitable that the chip 108 does not move around after being located within the recess 106, in anticipation of the wire ends 110a, 110b being bonded to the terminals 108a, 108b.

As best viewed in FIG. 1E, an antenna wire 110 is disposed on a top surface (side) of the substrate 104, and may be formed into a flat (generally planar) coil, having two end portions 110a and 110b.

As best viewed in FIG. 1F, the antenna wire 110 is “mounted” to the substrate 104a, which may comprise “embedding” (countersinking) the antenna wire into the surface of the substrate, or “adhesively placing” (adhesively sticking) the antenna wire on the surface of the substrate. The wire typically feeds out of a capillary 116 of an ultrasonic wire guide tool (or “sonotrode”, not shown). The capillary 116 is typically disposed perpendicular to the surface of the substrate 100. The capillary 116 is omitted from the view in FIG. 1E, for illustrative clarity.

The antenna wire 110 may be considered “heavy” wire (such as 60 μm) and requires higher bonding loads than those used for “fine” wire (such as 30 μm). Rectangular section copper ribbon (such as 60×30 μm) can be used in place of round wire.

The capillary 116 may be vibrated by an ultrasonic vibration mechanism (not shown), so that it vibrates in the vertical or longitudinal (z) direction, such as for embedding the wire in the surface of the substrate, or in a horizontal or transverse (y) direction, such as for adhesively placing the wire on the surface of the substrate. In FIG. 1F, the wire 110 is shown slightly spaced (in drawing terminology, “exploded” away) from the substrate, rather than having been embedded (countersunk) in or adhesively placed (stuck to) on the surface of the substrate.

The antenna wire 110 may be mounted in the form of a flat coil, having two ends portions 110a and 110b. The ends portions 110a and 110b of the antenna coil wire 110 are shown extending over (FIG. 1E) and may subsequently be connected, such as by thermo-compression bonding (not shown), to the terminals 108a and 108b of the transponder chip 108, respectively.

Examples of embedding a wire in a substrate, in the form of a flat coil, and a tool for performing the embedding (and a discussion of bonding), may be found in U.S. Pat. No. 6,698,089 (refer, for example, to FIGS. 1, 2, 4, 5, 12 and 13 of the patent). It is known that a coated, self-bonding wire will stick to a synthetic (e.g., plastic) substrate because when vibrated sufficiently to soften (make sticky) the coating and the substrate.

In FIG. 1F, the wire 110 is shown slightly spaced (in drawing terminology, “exploded” away) from the terminals 108a/b of the transponder chip 108, rather than having been bonded thereto, for illustrative clarity. In practice, this is generally the situation—namely, the end portions of the wires span (or bridge), the recess slightly above the terminals to which they will be bonded, in a subsequent step. Also illustrated in FIG. 1F is a “generic” bond head, poised to move down (see arrow) onto the wire 110b to bond it to the terminal 108b. The bond head 118 is omitted from the view in FIG. 1E, for illustrative clarity.

The interconnection process can be inner lead bonding (diamond tool), thermo-compression bonding (thermode), ultrasonic bonding, laser bonding, soldering, ColdHeat soldering (Athalite) or conductive gluing.

As best viewed in FIG. 1E, due to the layout of the antenna coils, the antenna wire 110 needs to cross over itself. This is illustrated in the dashed-line circled area “c”. In order to prevent shorting (electrical contact between different portions of the antenna coil) the antenna wire should be an insulated wire, generally comprising a metallic core and an insulation (typically a polymer) coating. Also, the polymer coating facilitates the wire being “adhesively placed” on (stuck to) a plastic substrate layer (such as 104a). (In some cases, the antenna wire does not need to cross over itself. See, for example, FIG. 4 of U.S. Pat. No. 6,698,089).

In order to feed the wire conductor back and forth through the ultrasonic wire guide tool, a wire tension/push mechanism (not shown) can be used or by application of compressed air it is possible to regulate the forward and backward movement of the wire conductor by switching the air flow on and off which produces a condition similar to the Venturi effect.

By way of example, the wire conductor can be self-bonding copper wire or partially coated self-bonding copper wire, enamel copper wire or partially coated enamel wire, silver coated copper wire, un-insulated wire, aluminum wire, doped copper wire or litz wire.

The inlay substrate 104a may comprise PVC, PC, PE, PET, PETE, TYVEK, TESLIN, Paper or Cotton/Noil.

A cover layer (not shown) can be disposed over the inlay substrate 104a for the final product, which may be an e-ID card. See. FIG. 1B.

The conventional method of embedding an insulated copper wire into a synthetic substrate is described in U.S. Pat. No. 6,233,818 and U.S. Pat. No. 6,698,089 in which an ultrasonic converter is bolted to a sonotrode having a capillary hole to allow the passage of wire from the side of the sonotrode to the tip. The ultrasonic converter coaxially induces vibrations into the sonotrode, thus creating localized friction and heat against the wire emerging from the tip of the sonotrode with a synthetic substrate. The wire is embedded into the substrate by inducing vibrations into the sonotrode and applying pressure, while at the same time moving the complete assembly to route the wire into the substrate to create an antenna with several turns. Embedding wire into a synthetic substrate such as PVC with a soft texture and low melting point can be accomplished using the conventional technique, but countersinking an antenna wire into a Teslin™ substrate, requires the additional procedure after the wire embedding process of pre-pressing the Teslin™ inlay in a lamination press.

Mounting an antenna wire to an inlay substrate by “embedding” or “adhesively attaching” have been mentioned, and are suitable for producing inlay substrates of secure documents, such as electronic passports. However, some of the techniques for producing electronic passports discussed herein may also be applicable to inlay substrates wherein the antenna comprises traces on an etched PWB (printed wiring board) or printed antenna (conductive ink) substrates. See, for example, U.S. Pat. Nos. 6,379,779; 6,406,935; 7,000,845; 7,449,212; and US Patent Publication Nos. 20090066076 and 20090115185, all of which are incorporated by reference herein.

An Example of Forming an Electronic Passport Cover (e-Cover)

The production of an electronic passport cover (such as shown FIG. 1A) in may involve the adhesive attachment of an inlay substrate with a cover layer.

FIG. 1G is a plan view illustrating an “inlay”, (or “passport inlay”, or “e-cover inlay”) for preparing three (3) “passport covers” (such as shown in FIG. 1A). The cover layer 104 is shown partially, so as to reveal the underlying inlay substrate 108. FIG. 1H is a cross-sectional view through FIG. 1G.

FIGS. 1G and 1H illustrate an e-cover inlay 100 having a “front” portion and a “back” portion, and comprising:
a cover layer (cover material) 104, such as approximately 350 μm thick; and
an inlay substrate 108, such as approximately 356 μm thick (14 mils) Teslin™

The material for the cover layer 104 may be PVC coated offset board or acrylic coated cotton, embossed and thermo-resistant. In the case of the fabric material, the backside coating can be water-base coated (aqueous/non-solvent), synthetic coated or have no coating. The front side coating can have two base coatings and one top coating of acrylic. An alternative to acrylic coating is peroxylene-based coating (nitrocellulose). The fabric can have a strong bias (diagonal) in the weave (drill weave as opposed to linear weave) which gives it high tensile strength and restricts the elongation. The leather embossing grain can have the resemblance of the skin of a kid goat or sheep (skiver) and is applied using an embossing cylinder drum at a pressure of 60 tons at around 180 degrees Celsius (° C.). Because of the front and backside coatings the fabric is not porous.

The material for the cover layer 104 may be a cloth product, with chemistry in the coatings and a leather-like appearance to the cloth, such as by Holliston Inc. (905 Holliston Mills Road, Church Hill, Tenn. 37642; www.holliston.com)

The material for the inlay substrate 108 may be Teslin™, a waterproof synthetic film, single-layer, uncoated with a thickness of 356 microns.

The material for the inlay substrate 108 may be PVC, PC, PE, PET, PETE, TYVEK, TESLIN, Paper or Cotton/Noil. The inlay substrate can also have special markings such as luminous threads, water marks, microscopic filings and optical polymer memory for additional security.

The inlay format is typically “3up” (for making three passport covers at once), and is generally planar and rectangular, having exemplary overall dimensions of 404.81 mm×182.56 mm×0.70 mm (thick). Each one of the three covers (A), (B) and (C) are generally rectangular, having exemplary dimensions of (404.81 mm/3)=134.94 mm×182.56 mm, with a thickness of 0.70 mm. In FIG. 1G, “A”, “B” and “C”, each are a “transponder site” for a given passport cover.

The inlay substrate 108 may be prepared with index slots, holes, windows for the 3 chip modules' mold mass and hinge gaps for the passport covers, and is then cut into sheets. The approximate width of the Teslin™ substrate is 248 mm, whilst the cover layer is approximately 216 mm with a Teslin™ margin of 14 mm one side and 18 mm on the other side (248=216+14+18).

A hinge gap 106 may be cut or punched through the inlay substrate 108 and the cover layer 104, separating the “front” portion from the “back” portion of the passport cover(s).

An RFID chip module 110 and corresponding antenna wire 120 are disposed in the inlay substrate 108.
the chip module 110 may be a leadframe-type chip module comprising a chip encapsulated by a mold mass 112 and a leadframe 118.
the mold mass may be approximately 240 μm thick and 5 mm wide
the leadframe 118 may be approximately 80 μm thick and 8 mm wide.
the chip module 110 may have an overall size of 5.1×8.1 mm, encapsulation size: 4.8×5.1 mm, leadframe thickness: 75 to 80 μm and overall thickness of the module (leadframe and mold mass) approximately 320 μm.
the antenna wire 120 may comprise 4 or 5 turns of wire, such as approximately 80 μm diameter (thick) wire. Ends of the antenna wire 120 are connected to the leadframe 118.

The inlay substrate 108 may be prepared by embedding an insulated wire (such as 80 μm) into the inlay substrate 108 to form an antenna 120 with 4 turns and interconnecting the wire ends of the antenna to a leadframe chip module by means of thermo-compression bonding.

The leadframe chip module 110 may include a mold mass, such as epoxy or resin, surrounding a silicon die on the leadframe 118.

The chip module 110 may be disposed in a recess 116 in the inlay substrate. The recess 116 may be slightly wider than the module. The recess 116 may be a “stepped” recess, as shown, and may be a “window” recess extending completely through the inlay substrate 108. Normally, the opening of the recess 116 at the bottom of the inlay substrate 108 is left open, revealing the mold mass 112 (flush with the bottom surface), which presents security problems.

The recess 116 may have a larger cross-dimension at the top surface of the inlay substrate 108 to accept the protruding leadframe 112 on each side of the chip module, and this larger portion of the recess may be formed by using an ultrasonic stamp to create a dent (depression) into the top surface of the inlay substrate 108.

A stepped recess, such as the recess 116 shown in FIG. 1H may be created in a single layer by first forming a window opening through the layer, then compressing the layer (such as the inlay substrate 108) to form a “shoulder” (region of reduced cross-dimension) around a periphery of the window opening. See US 20090091424 (Rietzler, 2009), which may be incorporated by reference herein.

The cover layer 104 may be laminated (joined) to the inlay substrate 104 using a polyurethane hot melt adhesive 114, such as approximately 50-80 μm thick. Prior to the adhesive process, the inlay substrate may be pre-pressed to ensure that the antenna wire does not protrude over (extend above) the surface of the Teslin™ substrate, in other words, to ensure that the antenna wire is fully embedded in the inlay substrate.

Non-reactive adhesives based on polyamide are typically not used in electronic passports for security reasons, as it would be possible to de-laminate the material by applying heat. Instead, reactive adhesive, moisture curing hot melt adhesive based on polyurethane, is used. Many are available.

The adhesive can be characterized by a high initial tack and a long open time (several minutes) or a short setting time (several seconds). In the latter case, the adhesive has to be reactivated using infra-red light before the cover layer is attached to the inlay, or hot laminated within a certain period (within 1 to 2 hours). The adhesive cures exclusively in the presence of moisture and gains its final strength after 3 to 7 days.

The adhesive may be applied to the cover layer (cover material) at approximately 150 degrees Celsius, putting down a layer of 50 to 80 microns (μm). The inlay is applied to the cover layer (cover material) in web or in sheet form, and is then laminated together using a roll press. Thereafter, the laminated inlay with the cover layer (cover material) is cut to size and stored in a stack for 3 to 7 days in a storage area having a regulated temperature and humidity.

Some Technical (Physical) Problems Associated With Using Hot-Melt Adhesive

The technique of applying moisture-curing hot melt based on polyurethane to a cover material processed in web form may have a number of drawbacks:

The back side of the cover material has a non-smooth (grained) texture which prevents a homogenous layer of adhesive coating being applied, irrespective of the coating applicator such as slot nozzle, screen printing, spray applicator or flexo/gravure roller. In the event of over-coating in a humid environment, leaving an uneven thickness of adhesive on the cover layer, the probability of CO2 emission after lamination is quite high. The release of CO2 gas from the adhesive layer results in the formation of bubbles between the cover material and the Teslin inlay.

The tensile strength properties and the thermal expansion coefficient of the cover material differ significantly from that of Teslin™. During the coating process in which adhesive is applied to the cover material at approximately 150° Celsius and thereafter during the roll press lamination process to reactivate the adhesive at 125° Celsius, the Teslin™ inlay held at room temperature is positioned onto the cover material, meaning that the different thermal expansion of the substrates can lead to sideways displacement of the finished product. This mechanical displacement results in the so-called “banana effect” in which the electronic passport cover is curve shaped (warped).

As the cover layer (cover material) in web form is stretched across drums during the coating and lamination processes, the cover layer (cover material) memorizes the curved shape of the drums which can present a problem during curing. If the final product is stored in stacks under the pressure of a weight, separated by paper sheets, in a non-controlled temperature and humidity environment, the optimal curing time of 3 to 7 days will vary significantly according to production batches. The resulting effect of a short curing time is the warping of the final product.

Apart from the formation of bubbles and the warping of the final product, the longevity of the electronic passport could be reduced by moisture seeping into the exposed area around the mold mass of the chip module.

Some Security Concerns Regarding Secure Documents

Apart from the above “technical” issues (physical problems) which impinge on the quality, reliability and longevity of secure documents, there may be a number of additional concerns surrounding (i) security and (ii) the type of chip module (such as leadframe module, or epoxy glass module) used, for example, in a passport inlay.

To prevent or indicate tampering of the area surrounding the chip module, it is advantageous to hide the transponder chip or chip module and the wire interconnections thereto in the inlay substrate layer to enhance protection against falsification. Security elements may also be designed in particular as optically variable elements, such as holograms, electroluminescent pigments, or interference layer elements for example which, when viewed, give different color impressions depending on the viewing angle.

One of the impediments in hiding the transponder chip module and the wire interconnections thereto in the inlay substrate layer (thickness: 356 microns) has been the thickness of the chip module with 320 microns. In addition, metal leadframe chip modules mounted to an inlay substrate tend to break during torsion and bending of the substrate. Semiconductor companies have reduced the footprint and thickness of the chip module down to 250 microns, by packaging the transponder chips as a flip-chip module, glass epoxy module, plastic leadframe module or as naked die connected directly to the wire ends of an antenna.

To prevent external skimming of the data stored in the transponder chip when a passport is closed, it is desired that an electromagnetic shield be integrated into the front and back cover of a passport cover. See, for example, US 20070205953 (Axalto), incorporated in its entirety by reference herein.

### SUMMARY OF THE INVENTION

It is a general object of the invention (as may be disclosed herein, or in the parent applications) to provide improved techniques for use in the manufacture of security documents, and security documents (the “product”) having improved technical and security features. For example,
improvements in the manufacture of the product to reduce warpage and breakage in the product, and to integrate and hide the chip module and the wire interconnections in an inlay substrate layer of the product and add security features to make alteration of the product and/or the production of forgeries technically impossible or at least uneconomical.
unauthorized separation of the cover material and inlay substrate mechanically or through de-lamination should result in the destruction of the chip module and the antenna
to prevent skimming of the personal data stored in the memory of an RFID chip in an electronic passport by activating the secure document with correct keys at close proximity or eavesdropping by intercepting the communication between a reader and an electronic passport, shielding is required.

Some features and embodiments disclosed herein may be concerned with techniques to protect a chip module from moisture and mechanical shock using a adhesive patch; to hide an antenna in a multi-layered construction; to create recesses in a substrate to accommodate a chip module leadframe using laser ablation instead of compressing the material to form a recess; to loop the wire ends of an antenna adjacent to the terminals areas of a chip module in preparation for interconnection, and to embed a wire conductor into a substrate using a wire guide assembly consisting of an ultrasonic converter, aluminum block directing the ultrasonic energy and a sonotrode.

Other features disclosed herein may be concerned with security issues: to hide a chip (die, leadframe chip module, epoxy glass chip carrier, etc) in a substrate using stepped recesses to accommodate the chip and a patch or patches to protect the chip and the wire interconnections thereto; to integrate security features into the inlay such as a hologram, metal security strip or an electronic ink display which can be activated by the electro-magnetic field driving the RFID chip, —and to shield a transponder unit in a passport cover from authorized skimming when the passport cover is closed, by adding metallic pigments to the adhesive layer bonding the cover layer to the inlay substrate.

An inlay substrate for a secure document having a recess extending into the inlay substrate from a first (top) surface thereof for receiving a chip module therein, and an antenna wire disposed in the inlay substrate and connected with the chip module, the inlay substrate comprises: at least two layers of a synthetic material, such as Teslin™, laminated to one another with a layer of adhesive. The chip module may be a leadframe-type module or an epoxy glass type module.

The antenna wire may be disposed on a top one of the at least two layers, or between the at least two layers.

The recess may be straight or stepped. The recess may be a pocket-type recess extending only partially through the substrate or a window-type recess extending completely through the inlay substrate. The recess may be formed by laser ablation, or by freezing the material of the inlay substrate and machining (milling) it.

A moisture-resistant patch may cover the chip module. An epoxy filling may be disposed in the recess, surrounding the chip module and the antenna wire interconnections. A lid may covering an opening of the recess.

Channels may be formed (pre-formed) in a surface of the substrate within which the antenna wire is at least partially embedded. The channels may be formed by removing material or displacing material. The channels may be formed by at least one of (i) laser ablation, (ii) gouging, (iii) ultrasonic stamp, and (iv) heating and molding.

The channels define a pattern for the antenna. An antenna wire may be mounted in the channel.

Rather than using antenna wire, the channels may be filled with a flowable, conductive material to form the antenna. Techniques are disclosed for connecting the flowable, conductive material with terminals of a chip module.

Ferrite material may be incorporated into the inlay substrate to reflect or absorb electromagnetic energy. Various embodiments are disclosed.

A cover layer may be laminated to the inlay substrate. The cover layer and inlay substrate may comprise an inlay, such as for a passport booklet (cover) having a front panel and a back panel. A shielding/detuning antenna may be disposed on the back panel of the passport cover. A switch may be disposed in the passport cover for disconnecting the chip module's antenna when the passport booklet is closed.

According to the invention, generally, a secure document such as a passport may be made by installing an RFID chip module into an opening of a substrate carrying an antenna, connecting the antenna with the RFID chip module, then applying an adhesive over the substrate, antenna, RFID chip module, and connections. Then a second substrate having an opening for accommodating the RFID chip module may be mounted, such as by laminating, to the substrate having the antenna and RFID chip module. Method and apparatus are disclosed.

In their various embodiments, the invention(s) described herein may relate to industrial and commercial industries, such RFID applications, payment smartcards, electronic passports, identity cards, access control cards, wearable devices the like.

Other objects, features and advantages of the invention(s) disclosed herein, and their various embodiments, may become apparent in light of the descriptions of some exemplary embodiments that follows.

### BRIEF DESCRIPTION OF THE DRAWINGS

Reference will be made in detail to embodiments of the disclosure, non-limiting examples of which may be illustrated in the accompanying drawing figures (FIGs). The figures may generally be in the form of diagrams. Some elements in the figures may be exaggerated, others may be omitted, for illustrative clarity.

Any text appearing in the drawings is incorporated by reference herein. The figures are intended to be illustrative, not limiting. Although the invention is generally described in the context of these embodiments, it should be understood that it is not intended to limit the invention to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element). It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

FIG. 1A is a perspective view of a security document which is a passport cover (e-cover), according to the prior art.

FIG. 1B is a perspective view of a security document which is an electronic identification card (eID), according to the prior art.

FIG. 1C is a perspective view of a chip module which is a leadframe module, according to the prior art.

FIG. 1D is a perspective view of a chip module which is an epoxy-glass module, according to the prior art.

FIG. 1E is a top view of a transponder site (one of many on an inlay sheet), according to the prior art.

FIG. 1F is a side, cross-sectional view, partially exploded, of a wire being mounted to the an inlay substrate and bonded to the terminals of a transponder chip, according to the prior art.

FIG. 1G is a top view of an inlay sheet for making e-covers, having three “transponder sites” (“3up”), according to the prior art.

FIG. 1H is a side, cross-sectional view, partially exploded, of an e-cover of FIG. 1G.

FIG. 2A is a cross-sectional view, illustrating a passport cover comprising a multi-layer inlay substrate and a patch covering a chip module in a recess of the inlay substrate, according to an embodiment of the invention.

FIG. 2B is a cross-sectional view, illustrating a passport cover comprising a multi-layer inlay substrate and a patch covering a chip module in a recess of the inlay substrate, according to an embodiment of the invention.

FIGS. 2C, 2D and 2E are cross-sectional views showing a method of making the passport cover in FIG. 2B, according to an embodiment of the invention.

FIG. 2F is a cross-sectional view, illustrating a passport cover comprising a multi-layer inlay substrate and a patch covering a chip module in a recess of the inlay substrate, according to an embodiment of the invention.

FIG. 2G is a cross-sectional view, illustrating a passport cover comprising a multi-layer inlay substrate and a patch covering a chip module in a recess of the inlay substrate, according to an embodiment of the invention.

FIG. 2H is a cross-sectional view, illustrating a passport cover comprising a multi-layer inlay substrate and a chip module in a pocket-type recess of the inlay substrate, according to an embodiment of the invention.

FIG. 2I is a cross-sectional view, illustrating a passport cover comprising a multi-layer inlay substrate and a chip module in a pocket-type recess of the inlay substrate, according to an embodiment of the invention.

FIG. 2J is a cross-sectional view, illustrating a passport cover comprising a single layer inlay substrate and a chip module in a pocket-type recess of the inlay substrate, according to an embodiment of the invention.

FIG. 3A is a diagram (exploded cross-sectional view) of a construction of a passport laminate, before lamination.

FIG. 3B is a diagram (cross-sectional view) of a construction of a passport laminate, after lamination.

### DETAILED DESCRIPTION

Various embodiments of the invention will be presented to illustrate the teachings of the invention(s). An embodiment is an example or implementation of one or more aspects of the invention(s). Although various features of the invention(s) may be described in the context of a single embodiment, the features may also be provided separately or in any suitable combination. Conversely, although the invention(s) may be described herein in the context of separate embodiments for clarity, the invention(s) may also be implemented in a single embodiment.

The relationship(s) between different elements in the figures may be referred to by how they appear and are placed in the drawings, such as “top”, “bottom”, “left”, “right”, “above”, “below”, and the like. It should be understood that the phraseology and terminology employed herein is not to be construed as limiting, and is for descriptive purposes only.

The invention relates generally to inlays and techniques for making the inlays, including technical features and security features. As used herein, an “inlay” may be a single- or multi-layer substrate containing HF (high frequency) and/or UHF (ultra-high frequency) radio frequency identification (RFID, transponder) chips and/or modules. These inlays may be used in secure documents, such as, but not limited to, electronic passports (ePassports) and electronic ID (eID) cards.

In the following descriptions, some specific details may be set forth in order to provide an understanding of the invention(s) disclosed herein. It should be apparent to those skilled in the art that these invention(s) may be practiced without these specific details. Any dimensions and materials or processes set forth herein should be considered to be approximate and exemplary, unless otherwise indicated. Headings (typically underlined) may be provided as an aid to the reader, and should not be construed as limiting.

Some processes may be presented and described in a series (sequence) of steps. It should be understood that the sequence of steps is exemplary, and that the steps may be performed in a different order than presented, some steps which are described may be omitted, and some additional steps may be omitted from the sequence and may be described elsewhere.

Reference may be made to disclosures of prior patents, publications and applications. Some text and drawings from those sources may be presented herein, but may be modified, edited or commented to blend more smoothly with the disclosure of the present application.

### Some Embodiments of the Invention

In the main, examples of electronic passport covers with inlay substrates having leadframe modules may be used to illustrate the embodiments. It should be understood that various embodiments of the invention(s) may also be applicable to other secure documents containing electronics (such as RFID and antenna), such as electronic ID cards. Secure documents may also be referred to as “electronic documents”. In the main hereinafter, secure documents which are passport inlays, typically cold laminated (with adhesive), are discussed.

The following embodiments and aspects thereof may be described and illustrated in conjunction with systems, tools and methods which are meant to be exemplary and illustrative, not limiting in scope. Specific configurations and details may be set forth in order to provide an understanding of the invention. However, it should be apparent to one skilled in the art that the invention(s) may be practiced without some of the specific details being presented herein. Furthermore, well-known features may be omitted or simplified in order not to obscure the descriptions of the invention(s).

It is a general object of the invention to create an RFID laminate for application in electronic passports and smartcards. The laminate may comprise two substrates, each of which may comprise synthetic material, paper, cotton, fleece or a combination thereof. A passive transponder (antenna connected to an RFID chip or chip module CM) may be disposed (sandwiched) between the two substrates. The transponder can transmit and receive data when in an electromagnetic field generated by a reader or terminal. The chip module may comprise an RFID chip (die) mounted and connected (such as by wire bonding) to a leadframe LF, and overmolded with a mold mass MM.

The transponder can reside on one of the two substrates, and this substrate is referred to as an “inlay” or “inlay substrate” hereinafter. The other of the two substrates may be referred to as the “leadframe” substrate.

The thickness of the laminate (inlay substrate+leadframe substrate) should approximately match (equal) the approximate thickness of the RFID chip module CM, while at the same time protecting the chip module CM and its antenna interconnections from the environment.

The laminate should also meet ISO requirements, in particular bending and torsion tests, and the surface finish should have a smooth texture leaving no indents, for example in the cover material of a passport booklet, after lamination.

To achieve such an objective, the chip module CM should be processed in such a way so as to avoid tilting or movement of the chip module on the inlay substrate during its placement and interconnection with the end portions of the antenna. The antenna interconnections to the chip module should not be impaired by bending of the laminate, and the leadframe of the chip module should not sever such interconnections. Therefore, the fixation of the chip module and protection of the antenna interconnections are paramount for reliability and durability of the final product.

The use of an adhesive patch at an opening in an inlay substrate to accommodate the mold mass side of a chip module may serve as a means for attaching the chip module to an inlay substrate and protecting the chip module from the environment, in particular from moisture seeping into the area surrounding the interconnections (and causing corrosion). The antenna connections may be made to the face-down side of the chip module, in other words to the underside of the leadframe where the mold mass encapsulates the wire bonded die.

In an embodiment of the invention, an adhesive layer may be used (i) as a sealant, to protect the interconnections, (ii) as a fixing mechanism for the chip module, and (iii) as an adhesive for adjoining the two substrates (inlay and leadframe substrates) together. The resulting stack-up of the laminate may comprise an inlay substrate with an opening or window for the mold mass side of the chip module with an antenna structure deposed in or on the inlay substrate with end portions connected to the face-up side of the chip module leadframe, and a leadframe substrate having an opening or window to accommodate the leadframe side of the chip module. The adhesive layer may be placed over the transponder side of the inlay substrate, substantially covering it in its entirety, and also covering the interconnections to the chip module. When this sandwich (inlay substrate/adhesive layer/leadframe substrate) is laminated, the adhesive bonds the two substrates together, seals the interconnections and flows to create a smooth surface at the areas of the openings in the two substrates.

The openings to accommodate the mold mass and leadframe of the chip module can be punched, cut or laser etched. One or both openings may have an adhesive patch to further protect the underlying areas of the chip module.

The adhesive layer may comprise a thermoplastic hot melt adhesive, reactive polyurethane adhesive, polyesterurethane film, polyetherurethane film, etc. The adhesive can be coated or applied as a film to the substrate or substrates.

The invention allows for there to be openings in the substrates, without the chip module falling out of one of these openings during production processing. This is important, for example, when the chip module is placed on the inlay or leadframe substrate, and before the antenna is deposed on the respective substrate and its end portions are connected to the chip module.

The antenna can be a wire wound coil, an embedded coil, an etched coil, a printed coil, or a coil transferred from a carrier substrate to the inlay or leadframe substrate. The wire may be insulated wire or self-bonding wire, and may have a thickness or diameter of 80 to 112 μm.

To achieve the objective that the RFID laminate is approximately the same thickness as the chip module, it is necessary that there be openings in the substrates to accept the mold mass and leadframe. In the case of the leadframe, the antenna interconnections are exposed, and need to be protected from the environment. The adhesive layer provides this protection while at the same time adhesively attaching the two substrates.

In the main, examples of electronic passport covers with inlay substrates having leadframe modules may be used to illustrate the embodiments. It should be understood that various embodiments of the invention(s) may also be applicable to other secure documents containing electronics (such as RFID and antenna), such as electronic ID cards. Secure documents may also be referred to as “electronic documents”. In the main hereinafter, secure documents, which are passport inlays, typically cold laminated (with adhesive), are discussed.

The following embodiments and aspects thereof may be described and illustrated in conjunction with systems, tools and methods which are meant to be exemplary and illustrative, not limiting in scope. Specific configurations and details may be set forth in order to provide an understanding of the invention. However, it should be apparent to one skilled in the art that the invention(s) may be practiced without some of the specific details being presented herein. Furthermore, well-known features may be omitted or simplified in order not to obscure the descriptions of the invention(s).

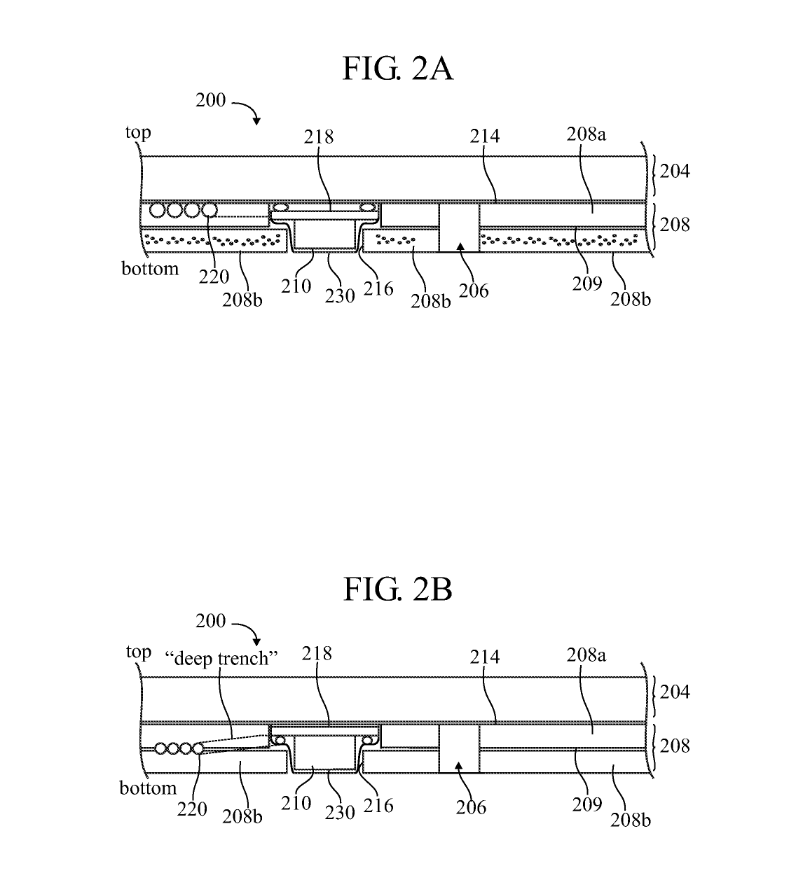

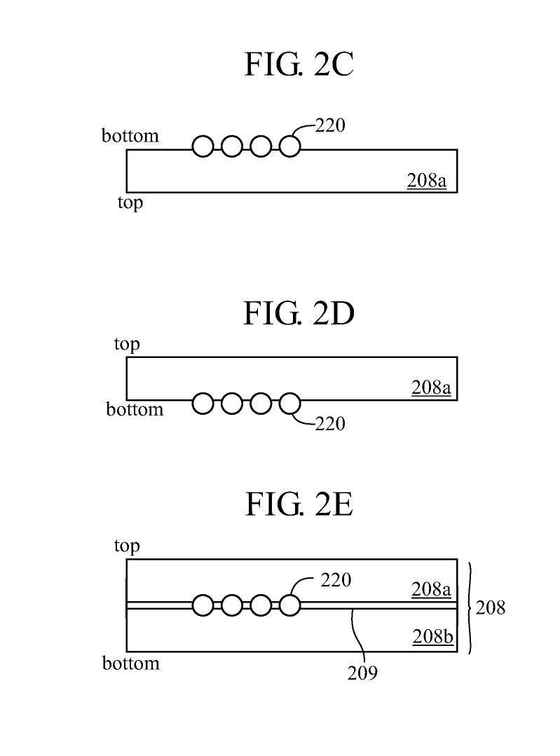

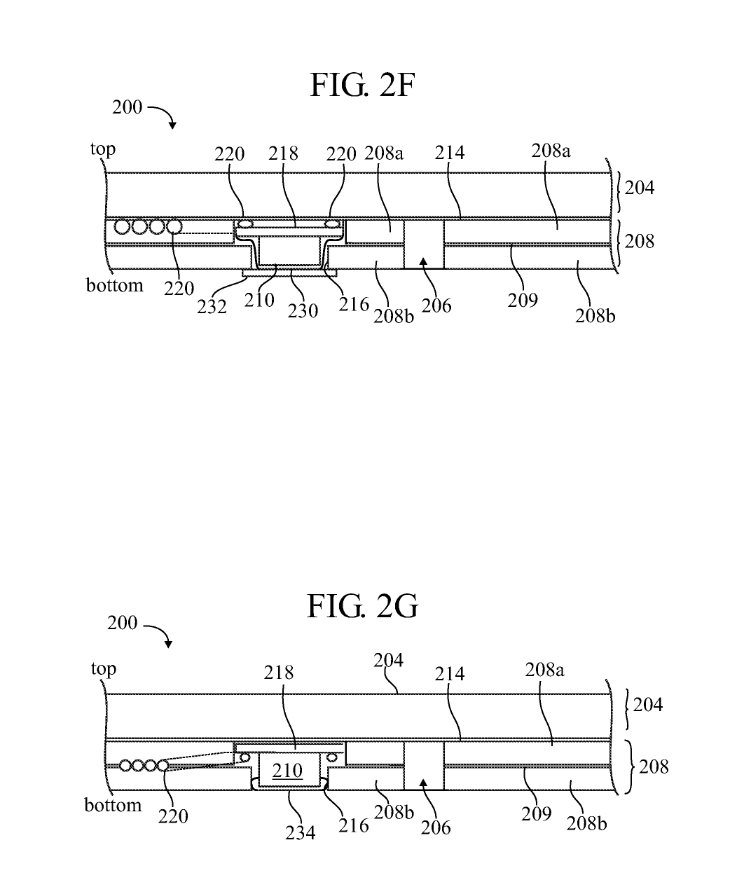

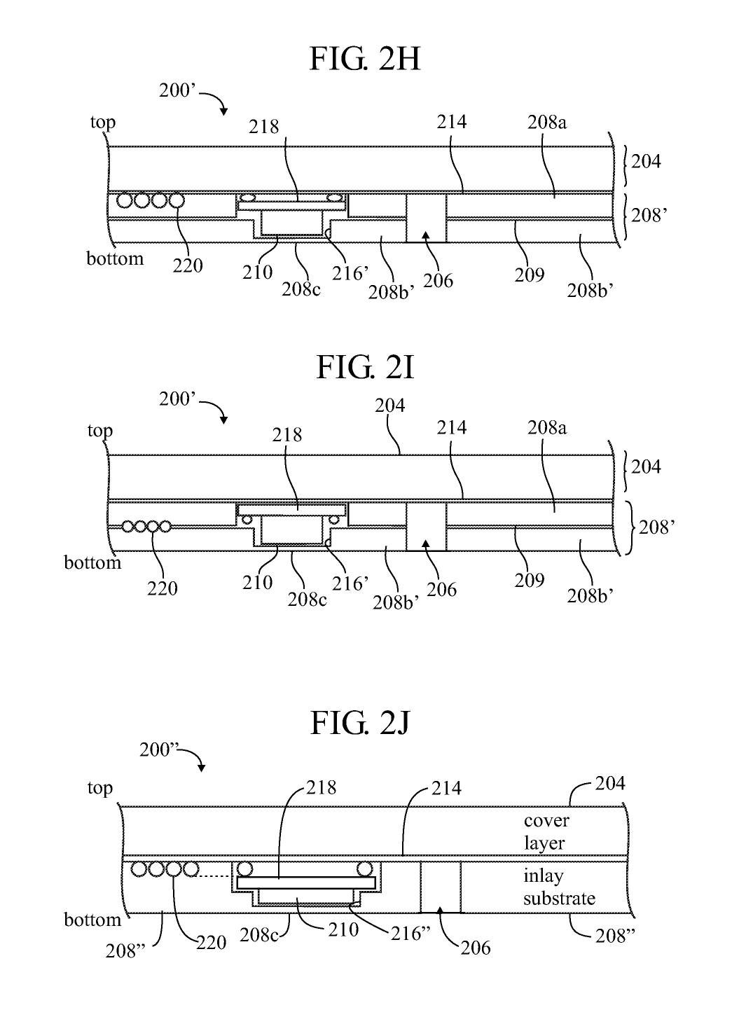

A Multi-Layer Inlay Substrate, and a Patch (FIGS. 2A, 2B)

FIGS. 2A and 2B illustrate embodiments of a secure document which is an inlay 200 suitable for use as a passport cover. The inlay 200 comprises a multiple-layer inlay substrate 208 and a cover layer 204 cold laminated (adhesively attached, joined) to the inlay substrate 208 with a layer 214 of adhesive such as 50 μm, which may be applied by roller coater.

A hinge gap 206 is shown in FIG. 2A (and in other figures). The hinge gap 206 may simply be a gap, approximately 1 mm wide, between a left (as viewed) portion of the inlay substrate 208 and a right (as viewed) portion of the inlay substrate 208. The left portion of the inlay 200 corresponds to the front of the passport cover, and the right portion of the inlay 200 corresponds to the back portion of the passport cover.

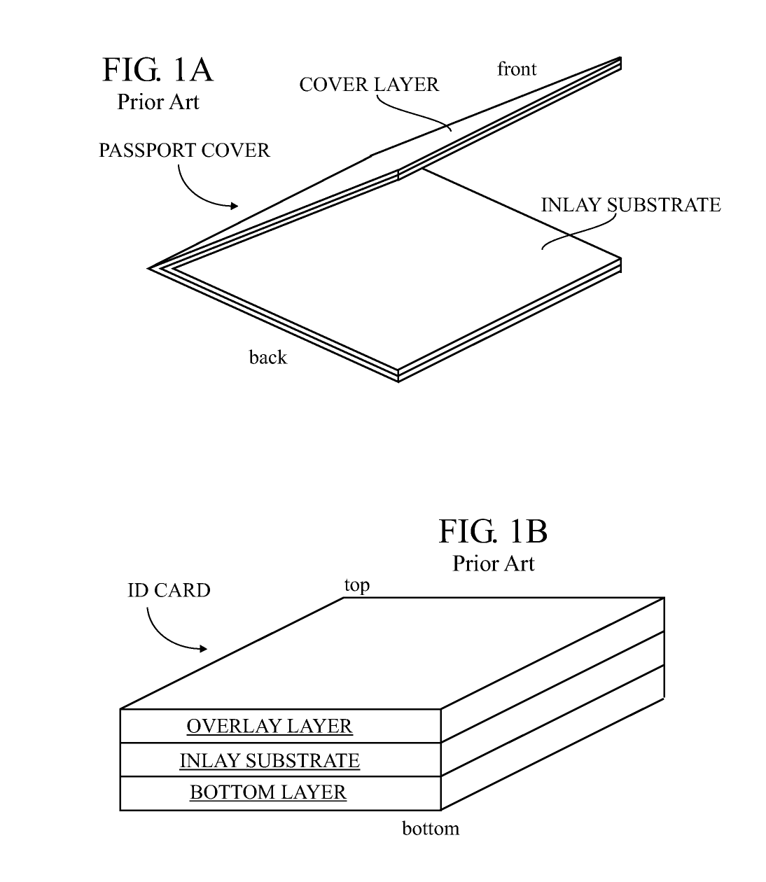

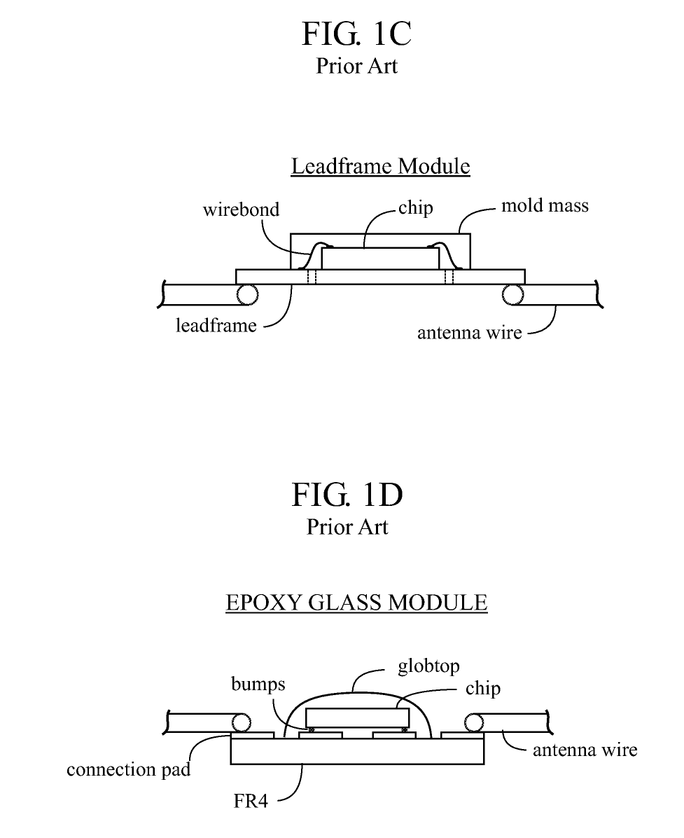

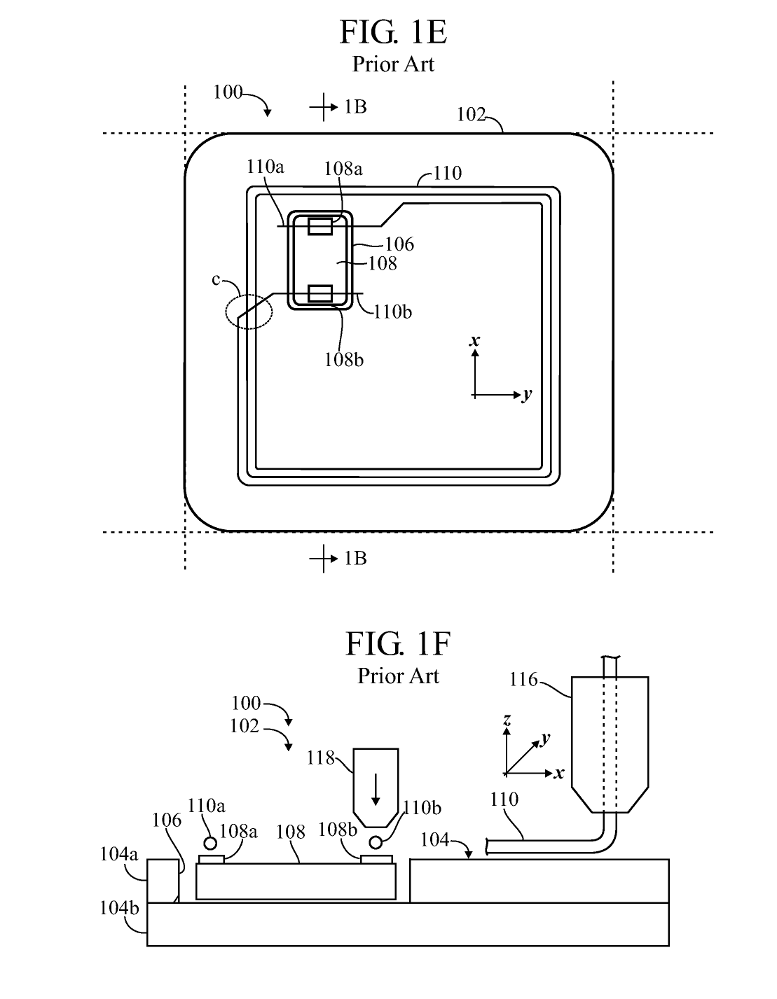

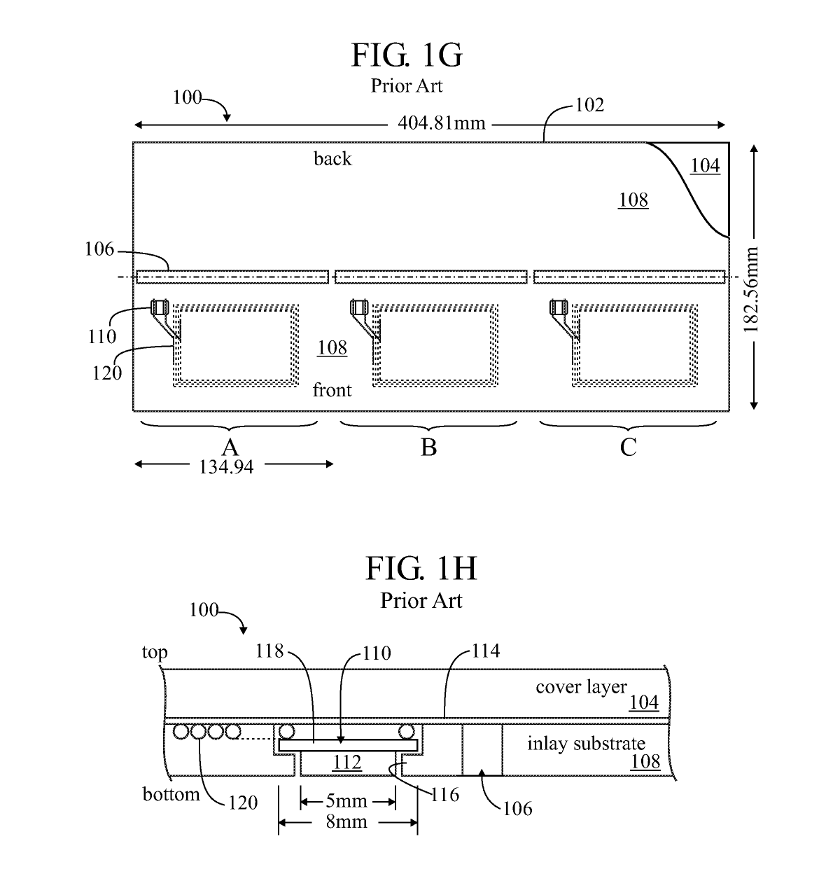

As illustrated by FIG. 1G, the hinge gaps 106 may not completely separate the back portion of the inlay substrate from the front portion, they are still joined by a “web”. Typically, the gap is punched or cut after adhesive coating and pre-press lamination (to smooth the surface)

The cover layer 204 is generally a planar sheet or layer of flexible, durable, often “textile-type” material, such as PVC, coated offset board, with or without optical bleacher or acrylic coated cotton.

The inlay substrate 208 (both layers 208a and 208b) is generally a planar layer or sheet of flexible, durable, typically “plastic-type” material, such as Teslin™, PVC, Polycarbonate (PC), polyethylene (PE) PET (doped PE), PETE (derivative of PE), and the like. The material of the inlay substrate may be referred to as “synthetic paper”.

The inlay substrate, or a bottom layer thereof (particularly when the antenna is embedded on a top surface of the top layer), can also be conductive, such as a ferrite-coated or ferrite-containing substrate to reflect or absorb electromagnetic energy.

As shown in FIGS. 2A and 2B, an antenna wire 220 is mounted to a top surface of the inlay substrate 208, and a chip module 210 is disposed in a recess 216 extending into the inlay substrate 208 from a top surface thereof. The antenna wire 220 may comprise 4 or 5 turns of wire, such as approximately 80 μm diameter (thick) wire. Ends of the antenna wire 220 are connected to terminals of the chip module 210.

The recess 216 may be a window-type recess extending completely through the inlay substrate 208 to the bottom surface thereof. of the inlay substrate.

The chip module 210 may be a leadframe-type chip module comprising a chip mounted on a leadframe 218 and encapsulated by a mold mass 212. The leadframe 218 may be approximately 80 μm thick and 8 mm wide. The mold mass 212 may be approximately 240 μm thick and 5 mm wide. The chip module 210 may have an overall size (width dimensions) of 5.1×8.1 mm and an overall thickness of 320 μm. The width of the recess 216 should be sufficient to accommodate the chip module (including leadframe 218), with some clearance.

The inlay substrate 208 comprises two or more layers 208a and 208b which are laminated (adhesively attached, joined) one another with a layer (or layers) 209 of adhesive such as 50-80 μm, which may be applied by a roller coater. In the main hereinafter, a two-layer example of an inlay substrate 208 will be described, comprising an upper (topmost) layer 208a and a lower (bottommost) layer 208b.

The recess 216 for the chip module 210 extends into the inlay substrate 208 from the top surface of the topmost layer 208a, through the topmost layer 208a, and at least partially into the bottommost layer 208b. The recess 216 extends fully through the entire inlay substrate 208, including fully through the bottommost layer 208a, exiting the inlay substrate 208 at the bottom of the bottommost layer 208b.

The recess 216 is “stepped” in that it has a larger width dimension opening at the top surface of the inlay substrate 208 than at the bottom surface of the inlay substrate 208. For example, a top portion of the recess 216, for accommodating the leadframe 218 has a width dimension of 5.3×8.1 mm, and a bottom portion of the recess 216 for accommodating the mold mass 212 has a width dimension of 5.1×5.1 mm

The stepped recess 216 may be formed by a first opening having a first width dimension in the topmost layer 208a, second opening having a second width dimension in the next adjacent (which is the bottommost) layer 208b. When the layers 208a and 208b are assembled with one another, the openings in the layers 208a and 208b are aligned (such as concentric) with one another. The first width dimension is different than the second width dimension. The first width dimension, for accommodating the leadframe, is shown greater than the second width dimension, for accommodating the mold mass.

The openings of the recess 216 in the layers 208a and 208b may be any appropriate shape, such as rectangular for a rectangular chip module or circular for a circular (round) chip module. The openings may be formed by a mechanical punch operation.

In the prior art (FIG. 1H), a stepped recess may be formed in a single layer inlay substrate 108. by compressing the substrate using an ultrasonic stamp. An advantage of forming the inlay substrate 208 with (at least) two layers 208a and 208b is that the stepped recess may be formed more easily, and precisely.

The chip module 210 may be disposed in the recess 216 in such a way that the leadframe 218 is nearly flush with the upper surface of the top substrate layer 208a and the mold mass of the chip module is nearly flush with a bottom side of the bottom substrate layer 208b. However, note that the end portions of the antenna wire 220 are connected (bonded) to the top surface of the leadframe 218 (opposite the chip and mold mass which are on the bottom surface of the leadframe 218. Also note that the diameter of the antenna wire 220 is decreased where it is bonded to the leadframe 218. For example, the 80 μm wire may be compressed to approximately 40 μm during thermo-compression bonding.

In the finished inlay substrate 208, which may be considered an “interim product”, all of the components (chip module 210 and antenna 220) mounted in or to the inlay substrate 208 should not project beyond the surface of the inlay substrate 208.

In FIG. 2A, the antenna wire 220 is embedded (disposed) in a top surface of the topmost substrate layer 208a, and is connected with a top surface of the leadframe 218.

In FIG. 2B, the antenna wire is embedded between the two adjacent inlay substrate layers 208a and 208b, such as in a top surface of the bottom substrate layer 208b, or in the bottom surface of the top substrate layer 208a.

FIG. 2B differs from FIG. 2A in that the antenna wire (which may be self-bonding wire) is disposed between the two substrate layers 208a and 208b (rather than atop the top layer 208a). This may be accomplished by:
first, with the top layer 208a inverted (bottom side up), partially embedding the antenna wire 220 into the bottom surface of the top layer 208a, without countersinking the antenna wire 220 entirely, leaving the antenna wire 220 to protrude above the layer. For example, the antenna wire 220 is embedded only approximately 30-70% of its diameter into the bottom surface of the top layer 208a, leaving 70-30% protruding above the bottom surface of the top layer 208a. Or, the antenna wire 220 is embedded only approximately 40% or 50% of its diameter into the bottom surface of the top layer 208a leaving 60% or 50%, respectively, protruding above the bottom surface of the top layer 208a. See FIG. 2C.
then, in a second step, the top layer 208a is flipped over (top side up), and is adhesively attached to the bottom layer 208b carrying the antenna, whereby the protruding antenna wire 220 is positioned face down onto the top surface of the bottom layer 208b, before lamination. In the lamination process, the antenna wire 220 sinks into the bottom layer 208b. The lamination process has also the advantage of “disguising” the position of the antenna in the two layered inlay substrate structure and creating a smooth and even surface on each external surface (top surface of the top layer, bottom surface of the bottom layer) of the multi-layered inlay substrate structure. See FIGS. 2D and 2E.
Another feature of FIG. 2B is the wire ends of the antenna are connected to the face-down side of the chip module leadframe.
An advantage of this inlay construction is that any attempt to peel the two layers apart, results in the destruction of the antenna and the wire interconnections to the chip module.

The chip module may be mounted face-down into the first layer 208a, then the antenna 208 is scribed into the opposite side of the first layer 208a, and the wire ends are connected to the chip module 210.

During the lamination process, the adhesive 209 compresses, some squeezes out, and some may get absorbed into the cover layer during the lamination process. After lamination, the adhesive layer 209 may be only 20 μm thick. The layers 208a and 208b may be “pre-pressed” with a hot laminator to smooth the surface and hide the wires.

During embedding of the antenna wire, the wires “mark” the inlay substrate. The material may be flattened by putting the inlay substrates through temperature and pressure for about 30 minutes.

A security feature of the antenna wire location (between the two layers) shown in FIG. 2B is that if an attempt is made to pull the chip module out of the inlay, this may destroy the interconnections and wire antenna.

It should be understood that there are various “combinations” of module orientation and interconnection location which may be shown in FIGS. 2A & 2B, 2F & 2G, 2H, 2I & 2J, 5B, 5G, 6A & 6B. Generally, the module can be mounted face down or face up and the interconnections thereto can be on the top of the module such as is the case with a leadframe or underneath the chip carrier (epoxy glass or leadframe).

FIGS. 2C, 2D and 2E show a method of making the inlay substrate 208 of FIG. 2B.
(FIG. 2C) with the top layer 208a inverted (or, invert the top layer 208a), so the bottom surface is facing up, partially embed the antenna wire 220 in the upward-facing bottom surface of the top layer 208a, leaving a portion of the (diameter of) the antenna wire protruding from the surface;
(FIG. 2D) flip over (un-invert) the top layer 208a so that its bottom surface is facing downwards (and top surface is facing upwards).
(FIG. 2E) laminate (with adhesive) the top layer 208a (which has the antenna wire protruding from the surface) to the bottom layer 208b, thereby embedding the protruding portion of the antenna wire 220 into the top surface of the bottom layer 208b.

Alternatively, the antenna wire 220 can first be partially embedded in the top surface of the bottom layer 208b, then in the lamination process, sunk into the bottom surface of the top layer 208a.

Alternatively, the antenna wire 220 can be positioned between two adjacent layers of the inlay substrate, then partially embedded into both layers, adhesively bonded and then laminated to form one cohesive electronic laminate layer. Any attempt to separate the two layers may result in the destruction of the antenna and the wire-end connections to the chip module.

Some additional exemplary dimensions for the inlay 200 are:
overall thickness of the inlay 200, approximately 700 μm (0.700 mm), including cover layer 204 and adhesive layers 214 and 209
thickness of the cover layer 204, approximately 300 μm
thickness of the inlay substrate 208, approximately 356 μm
thickness of each layer 208a and 208b of the inlay substrate 208, approximately 145 μm
thickness of the adhesive 209 joining the two inlay substrate layers 208a and 208b, approximately 50 μm
thickness of the adhesive 214 joining the cover layer 204 to the topmost layer 208 of the inlay substrate 208, approximately 50 μm

FIG. 2B also illustrates a “deep trench” formed extending from the bottom surface of the top layer, to within the top layer 208a, for routing the antenna wire 220 to the chip module 510. The formation of “channels” and “deep trenches” is discussed in greater detail hereinbelow, such as with respect to FIGS. 4A and 5D

An additional feature shown in FIGS. 2A and 2B is a patch 230 covering (overlying) the chip module 210 and connections with the antenna wire 220. For example, the patch 230 may be made of the same material as the substrate (such as Teslin™)-laminated, adhesively attaches, ultrasonic or laser welding—50 μm thick. This patch 230 is not exclusive to the inlay substrate 208, rather it could be used, for example, with the inlay substrate 108 of FIG. 1H.

In situations where the recess 216 extends completely through the inlay substrate 208, the patch 230 may seal the area of the chip module 210 from moisture. The patch 230 may be moisture-resistant.

The patch 230 can be antistatic, to protect the chip module from electrostatic discharge.

The patch 230 may comprise a material that is luminous under ultraviolet (UV) light, so that tampering with the patch can be exposed by presenting the inlay 208 to an ultraviolet light source. As is known,
To help thwart counterfeiters, sensitive documents (e.g. credit cards, driver's licenses, passports) may also include a UV watermark that can only be seen when viewed under a UV-emitting light. Passports issued by most countries usually contain UV sensitive inks and security threads. Visa stamps and stickers on passports of visitors contain large and detailed seals invisible to the naked eye under normal lights, but strongly visible under UV illumination. Passports issued by many nations have UV sensitive watermarks on all pages of the passport. Currencies of various countries' banknotes have an image, as well as many multicolored fibers, that are visible only under ultraviolet (UV) light.

FIGS. 2F and 2G illustrate embodiments of a secure document which is an inlay 200 suitable for use as a passport cover. A cover layer 204 is laminated with adhesive 214 to a multi-layer inlay substrate 208 comprising at least two layers 208a and 208b′ (prime), laminated with an adhesive 209 to one another. A chip module 210 comprising a chip (not shown), a leadframe 218 and a mold mass 212 is disposed in a recess 216 extending into the inlay substrate 208 from a top surface thereof, and the recess 216 is stepped.

FIG. 2F illustrates an embodiment of a secure document which is an inlay 200 suitable for use as a passport cover. This inlay is substantially the same as the inlay 200 shown in FIG. 2A (multi-layer inlay substrate 208, antenna wire 220 on top of top inlay substrate layer 208a), with the addition of a strip (or stripe) 232 of a material, such as metal or Mylar, having a thickness of approximately 10 μm applied around the area where the patch 230 and the inlay substrate 208 (the bottom of the bottom inlay layer 208b) meet, bridging any gap between the bottom of the patch 230 and the bottom of the inlay substrate 208. The stripe 232 crosses any void between the patch 230 and the bottom surface of the inlay substrate 208.

FIG. 2G illustrates an embodiment of a secure document which is an inlay 200 suitable for use as a passport cover. This inlay is substantially the same as the inlay 200 shown in FIG. 2B (multi-layer inlay substrate 208, antenna wire 220 between the two substrate layers 208a and 208b). However, rather than using a patch (230), an epoxy filling 234, which may be luminescent under UV light, may be disposed in the recess, surrounding the chip module and the antenna wire interconnections. This may provide evidence of tampering when exposed to an ultraviolet light source.

FIGS. 2H and 2I show “variations” of inlays shown in FIGS. 2A and 2B. In most respects, the inlays 200′ (prime) of FIGS. 2E and 2F are similar to the inlays 200 of FIGS. 2A and 2B. A cover layer 204 is laminated with adhesive 214 to a multi-layer inlay substrate 208 comprising at least two layers 208a and 208b′ (prime), laminated with an adhesive 209 to one another. A chip module 210 comprising a chip (not shown), a leadframe 218 and a mold mass 212 is disposed in a recess 216 extending into the inlay substrate 208 from a top surface thereof, and the recess 216 is stepped.

In FIG. 2H, in a manner similar to that shown in FIG. 2A, the antenna wire 220 extends along (within) the top surface of the top layer 208a, and connects to the top surface of the leadframe 218.

In FIG. 2I, in a manner similar to that shown in FIG. 2B, the antenna wire 220 is disposed between the top layer 208a and the bottom layer 208b, and connects to the bottom surface of the leadframe 218.

A feature shown in the embodiments of FIGS. 2H and 2I (and 2J), is that rather than the recess 216 being a “window-type” recess extending completely through the inlay substrate 208′ (prime), the recess 216′ (prime) is a “pocket-type” recess extending only partially through the inlay substrate 208′. In the embodiments of FIGS. 2H and 2I, the recess 216′ stops short of the bottom surface of the bottom layer 208b′, leaving (for example) approximately 10 μm of material 208c directly under the chip module 210. This essentially eliminates the need for the patch 230 (FIGS. 2A, 2B), since there is no opening at the bottom surface of the inlay substrate 208′ caused by the recess 216′.

At “first glance” it may appear that the multi-layer inlay substrate 208 is not significantly different than the “one or more” top layers 104a of the inlay sheet 100 shown in FIG. 1F. However, there are a number of significant differences, such as:
the layers of a credit card (including, if applicable, multiple layers of the inlay substrate) are hot laminated to one another
the layers of the passport booklet, such as the cover layer and the inlay layer (including, if applicable, multiple layers of the inlay substrate) are cold laminated to one another, with adhesives.
the credit card is much thicker, making it easier to conceal and protect the RFID chip
the antenna wire is embedded in a different plane
the layers of the inlay substrate 208 are adhesively attached to one another, attempts to separate the two layers is intended to result in the destruction of the chip module and the antenna. This is an important security feature.
The standard construction of a multi-layered inlay (such as suggested by the “one or more” top layers 104a) is to hot laminate the substrate together. There is no adhesive layer (209). This is generally not possible with a synthetic paper material like Teslin™.
1E and 1F are standard contactless card. 1F, if complete would have another layer on top 0.78 mm (For ID cards, this is important, as they all follow the ISO 7816 standard for dimensions.)
in a passport, the material of cover layer is different than material of inlay substrate
in the contactless card (FIG. 1F) the cover layer (not shown) would be of the same material as the layer 104.
The thickness of a credit card (FIG. 1F) is sufficient to cover and protect the chip and antenna. For example, 450 μm
With a passport (FIGS. 2A-2I), the chip module is approximately as thick as the inlay substrate (both are in the range of 300-400 μm). It is more difficult to protect the chip module 210 in the passport than in the credit card. (A credit card 450 μm thick, and the chip module is surrounded by the substrate layer. In the passport, the substrate does not cover the chip, entirely.)

In the embodiments described above, with respect to FIGS. 2A-2I, the inlay substrate layers (such as Teslin™) are adhesively attached to form the inlay substrate 208 integrating the transponder (chip module 210) in the center of the inlay 200. Any attempt to separate the two layers (208a, 208b) should result in the destruction of the inlay 200. Also the patch 230 protects the chip module 210.

FIG. 2J shows another variation on the inlay 200″ (double prime). Again, most of the elements are the same as for the inlays 200 and 200′, and the inlay 200″ is nearly identical to the inlay 200′. A cover layer 204 is laminated to the inlay substrate 208, an antenna 220 is mounted to the inlay substrate 208, and a chip module 210 is disposed in a stepped, pocket-type recess 216′. However, here, the inlay substrate 208″ (double prime) is formed in a single layer inlay substrate 208″.

Fabricating the Inlay (Passport Cover)

Various methods may be used to fabricate the passport cover (200) such as:
The first and second layers (208a and 208b) of the inlay substrate (208) may be adhesively attached to one another in sheet (rather than roll) format.
The cover material (204) may also be processed in sheet format by applying a layer of polyurethane hot melt adhesive with a short opening time using a roller coating machine.
The adhesive-coated cover material (204) may be positioned on the multi-layered inlay substrate and affixed at two (or more) points using an ultrasonic collator.
The inlay substrate (208) may then be laminated to the cover material (204) by reactivating the polyurethane hot melt adhesive in a hot roll or lamination press.
Instead of applying heat to the cover material, it can be advantageous to apply the heat to the inlay substrate at a temperature of approximately 120° Celsius by passing the cover and inlay substrate over a hot lamination roll, under a pressure of approximately 3 Bar.

The layers of the multi-layer inlay substrate (208) and the cover layer (204) may be handled in sheet format and not from a web or an endless reel during the coating and lamination processes in which the material, held under tension, is passed over hot and cold rollers. Web coating and laminating over rollers is the primary cause of curling of the finished product.

To avoid the so-called banana effect of curling inlays after adhesively attaching the cover layer to the inlay substrate, the reactive hot melt adhesive may be applied to the cover layer in sheet format. For security reasons, the peel strength of the laminated inlay with the cover layer should meet or exceed the ICAO standard (ISO/IEC 10373). This can be achieved by applying the correct thickness of adhesive during the coating stage, exerting the correct pressure and temperature during the reactivation stage and storing the finished product to complete the curing process in a moisture controlled environment.

An Alternative to Hot Melt Adhesive

In another embodiment of the invention, a solution is provided which minimizes the emission of CO2 gas resulting in the formation of bubbles between a passport cover layer and the underlying inlay substrate. Instead of applying hot melt adhesive to the structured cover layer resulting in an uneven thickness of adhesive, a thin layer of aliphatic adhesive (as opposed to aromatic adhesive) high in viscosity (34,000 mPas at 130° Celsius) may be applied with a short open time of several seconds to the inlay substrate using a slot nozzle system (with shims) See, for example, Jowat 628.80.

In order to be able to apply the aliphatic adhesive under light pressure to the inlay substrate, it is advisable that the slot nozzle head does not go against the “grain” of the protruding antenna wires at the position of the chip module. For this reason, the slot nozzle head applying the adhesive may be applied in the direction of the wire ends, and not in the direction of the antenna.

After applying the aliphatic adhesive, but before the aliphatic adhesive is reactivated, the hinge gaps may be punched in the inlay substrate. And, finally, the cover layer may be placed over the inlay substrate and laminated in a press to create the passport cover.

Mechanically Milling the Recess

A problem with mechanical milling a synthetic material such as Teslin™ is that it is a flexible (resilient, deformable). It is no problem to punch out a hole through a layer of Teslin™ and, as described above, a stepped opening can be made by compression.

According to a feature of the invention, a recess (stepped or straight) can be formed in a material such as Teslin™ used for the inlay substrate by mechanical milling, by first reducing the temperature of the Teslin™ to make it more rigid and machineable. For example, below −10° C., such as approximately −18° C. Refrigeration and cooling units are well known. The material may be removed from the refrigeration unit immediately prior to machining (milling) and/or may be maintained at a low temperature during machining, such as by directing a stream of cooled air at the workpiece.

Numerous recesses in inlay substrates are illustrated herein, and milling is well known. A suitable milling tool is available from IBAG Switzerland AG, operating at 30,000 to 60,000 RPM, moving at 1-4 meters per minute (mpm).

Incorporating Ferrite in the Construction

FIG. 9A of U.S. Pat. No. 8,608,080 (compare FIG. 2A, herein) illustrates a multi-layer inlay substrate 908 (compare 208). The inlay substrate 908 comprises an upper layer 908a (compare 208a) laminated with an adhesive 909 (compare 209) to a lower layer 908b (compare 208b). A cover layer 904 (compare 204) may be laminated with an adhesive 914 (compare 214) to the inlay substrate 908.

A ferrite layer (dots) can be created in a synthetic substrate layer 908b beneath the layer 908a in which the antenna wire 920 (or conductive material forming an antenna) is located, being applicable to all types of antennae such as wire embedded, etched or conductive ink antennae.

FIG. 9B of U.S. Pat. No. 8,608,080 illustrates that the inlay substrate layer 908a in which the antenna wire 920 is embedded may be a ferrite-coated synthetic layer (having a ferrite coating 908c). Since the antenna wire 920 is embedded in the ferrite-containing material, a coated (insulated) antenna wire, such as shown in FIG. 8A should be used. See, for example, Flexield Series Flexible Composite-Type Electromagnetic Shield Materials For 13.56 MHz RFID System, TDK Corporation, Tokyo Japan, incorporated by reference herein. See also U.S. Pat. No. 4,539,433, incorporated by reference herein. For a multi-layer inlay substrate, this could be the top layer (208a).

FIG. 9C of U.S. Pat. No. 8,608,080 illustrates that a recess (or cavity) may be created by mechanically milling or laser ablating a layer of the inlay substrate, then filling the recess with ferrite material (metal or nano-metal particles) and conductive polymers, to create a 3D ferrite-structured layer. Here, the lower layer 908b is provided with the recess 925 which is filled with ferrite particles. The recess 925 may extend completely through the layer 908b, or only partially through the layer 908b. After the ferrite filling is cured, the area may be sealed with a patch (not shown) of synthetic material.

The ferrite material can be applied using digital non-impact inkjet printing, conventional printing (flexography, gravure, screen printing, offset) or dispensing. The area of the ferrite layer is larger than the area occupied by the antenna, in order to ensure optimal reflection of the electromagnetic energy.

FIG. 9D of U.S. Pat. No. 8,608,080 illustrates that the recess to accommodate the ferrite material can also be produced by using multiple layers with a cavity or cavities in the center substrate layer or layers. Only the bottom layer 908b is shown, for illustrative clarity.

Here, the bottom layer 908b comprises a sandwich construction of a top layer 927a, a middle layer 927b and a bottom layer 927c. The middle layer 927b has a window-type recess 927 extending completely therethrough, and filled with ferrite material.

FIG. 9E of U.S. Pat. No. 8,608,080 (compare FIG. 9C) illustrates that the ferrite material may be disposed in a recess 929, such as in the top layer 908a, and after the ferrite filling is cured, the area may be sealed with a patch 930 of synthetic material. The antenna wire 220 can also be embedded into the same layer as the ferrite material and routed across the sealed patch 930 to form the antenna pattern.

The Parent Cases (Generally)

U.S. Pat. No. 8,608,080, incorporated by reference herein, describes secure inlays for secure documents such as a passport comprising an inlay substrate which may have laser ablated recesses within which a chip module is installed. Channels for an antenna wire may be formed in a surface of the substrate. Instead of using wire, the channels may be filled with a flowable, conductive material.

Patches homogenous with the substrate layer may be used to protect and seal the chip and interconnection area.

The inlay substrate may include two layers, and the antenna wire may be between the two layers. A moisture-curing polyurethane hot melt adhesive may be used to laminate a cover layer and the additional inlay substrate layers.

The adhesive layer may include metal nanoscale powder and ink for electro-magnetic shielding.

Additional security elements may include material that is optically changeable by an electro-magnetic field. Ferrite-containing layers may be incorporated in the inlay substrate.

Claims of U.S. Ser. No. 12/545,825 (U.S. Pat. No. 8,608,080)

1. An inlay substrate for a secure document having a recess extending into the inlay substrate from a first (top) surface thereof for receiving a chip module therein, and an antenna wire disposed in the inlay substrate, wherein: the inlay substrate comprises at least two layers of a synthetic material laminated to one another with a layer of adhesive; and the recess extends through a top of the two layers and at least into a bottom of the two layers.

2. The inlay substrate of claim 1, wherein:
the antenna wire is disposed between the at least two layers.

3. The inlay substrate of claim 1, wherein: the recess is stepped, and is formed by a first opening having a first width dimension in a first one of the at least two layers, and a second opening having a second width dimension in a second one of the at least two layers which is adjacent to the first one of the at least two layers and the second opening is aligned with the first opening; and the first width dimension is different than the second width dimension.

4. The inlay substrate of claim 1, wherein: the recess is a pocket-type recess extending only partially through the inlay substrate or a window-type recess extending completely through the inlay substrate.

5. The inlay substrate of claim 1, further comprising: a moisture-resistant patch covering the chip module.

6. The inlay substrate of claim 1, further comprising: an epoxy filling disposed in the recess, surrounding the chip module and the antenna wire interconnections.

7. The inlay substrate of claim 1, further comprising: pre-formed channels in a surface of the substrate within which the antenna wire is at least partially embedded.

8. The inlay substrate of claim 1, wherein: the chip module is a leadframe-type module or an epoxy glass type module.

9. The inlay substrate of claim 1, further comprising: at least one lid covering at least one opening of the recess.

10. The inlay substrate of claim 1, further comprising: a cover layer laminated to the inlay substrate.

11. The inlay substrate of claim 10, wherein: the cover layer and inlay substrate comprise an inlay, such as for a passport booklet (cover) having a front panel and a back panel.

12. The inlay substrate of claim 11, further comprising:
a shielding/detuning antenna disposed on the back panel of the passport cover.

13. The inlay substrate of claim 11, further comprising:
a switch disposed in the passport cover for disconnecting the chip module's antenna when the passport booklet is closed.

14. The inlay substrate of claim 1, wherein:
the antenna wire is disposed on a top surface of the top layer.

15. The inlay substrate of claim 1, further comprising:
ferrite particles in the bottom layer.

16. The inlay substrate of claim 1, wherein:
the recess extends through the bottom layer.

17. The inlay substrate of claim 16, further comprising:
a strip of material on a bottom surface of the bottom layer.

18. The inlay substrate of claim 16, further comprising:
an epoxy filling disposed in the recess.

19. A secure document comprising the inlay substrate of claim 1.

20. The secure document of claim 19, comprising:
a chip module disposed in the recess and connected with the antenna.

Claims of U.S. Ser. No. 14/062,846 (U.S. Pat. No. 8,955,759)

3. A method of making a secure document comprising an inlay substrate, comprising:
providing the inlay substrate as at least two layers of a synthetic material laminated to one another with a layer of adhesive; and
providing a recess for a chip module in the substrate;

further comprising:
disposing ferrite particles in at least one of the layers.

2. The method of claim 3, wherein:
the recess extends through a top of the two layers and at least into a bottom of the two layers.

4. The method of claim 3, further comprising:
disposing an antenna wire between the at least two layers.

5. The method of claim 3, further comprising:
forming the recess as a stepped recess having a first opening having a first width dimension in a first one of the at least two layers, and a second opening having a second width dimension in a second one of the at least two layers which is adjacent to the first one of the at least two layers and the second opening is aligned with the first opening.

6. The method of claim 3, further comprising:
forming the recess as a pocket-type recess extending only partially through the substrate.

13. The method of claim 3, further comprising:
forming the recess as a window-type recess extending completely through the inlay substrate.

7. A method of making a secure document comprising an inlay substrate, comprising:
providing the inlay substrate as at least two layers of a synthetic material laminated to one another with a layer of adhesive; and
providing a recess for a chip module in the substrate;
further comprising:
forming the recess by laser ablation.

11. The method of claim 7, wherein:

the recess extends through a top of the two layers and at least into a bottom of the two layers.

14. The method of claim 7, further comprising:
forming the recess as a pocket-type recess extending only partially through the substrate.

15. The method of claim 7, further comprising:
forming the recess as a window-type recess extending completely through the inlay substrate.

8. A method of making a secure document comprising an inlay substrate, comprising:
providing the inlay substrate as at least two layers of a synthetic material laminated to one another with a layer of adhesive; and providing a recess for a chip module in the substrate;
further comprising:
forming channels in a surface of the substrate within which an antenna wire may be at least partially embedded.

9. The method of claim 8, wherein:
the channels are formed by removing material or displacing material.

10. The method of claim 8, wherein:
the channels are formed by at least one of laser ablation, gouging, ultrasonic stamping, and heating and molding.

12. The method of claim 8, wherein:
the recess extends through a top of the two layers and at least into a bottom of the two layers.

### Additional Disclosure

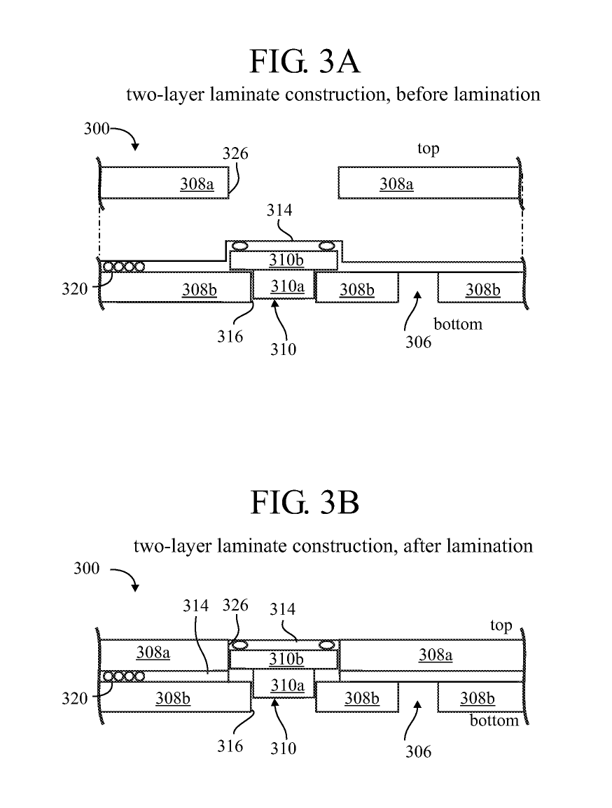

FIG. 3A is a cross-sectional view, illustrating a RFID laminate (or inlay, or passport laminate) 300 for a secure document such as an electronic passport, before lamination, comprising a leadframe (or substrate) 308a, an adhesive layer 314 and an antenna (or substrate) 308b, wherein the adhesive layer covering the antenna interconnections to the leadframe side of the chip module 310 in an opening 326 of the leadframe substrate 308a.

The antenna substrate 308b comprises an antenna structure 320 (such as an embedded wire antenna), an opening 316 in the substrate to accept the mold mass 312 of the chip module 310. The antenna substrate may also comprise a hinge gap 306. The hinge gap may have a width of approximately 7 mm. The antenna structure 320 may comprise copper wire having a diameter of approximately 112 μm, and may be embedded in or on the antenna substrate.

The antenna substrate 308b may comprise synthetic paper such as Teslin® and may have a thickness of approximately 178 μm (or approximately 254 μm) depending on the thickness of the mold mass 310a of the chip module 310. The mold mass 310a may have a thickness of approximately 250 μm.

The adhesive layer 314 may for example be a hot melt film having a thickness of 20 to 50 μm.

The leadframe layer (substrate) 308a may comprise a synthetic paper such as Teslin® and may have a thickness of approximately 178 μm (or approximately 152 μm) depending on the thickness of the leadframe portion (or simply “leadframe”) 310b of the chip module 310. The leadframe may have a thickness of approximately 80 μm.

An opening 326 may be provided in the leadframe substrate to accept the leadframe 310b portion of the chip module 310. The overall thickness of the chip module may be approximately 330 μm. The opening 326 may be aligned with the opening 316. The opening 326 may extend completely through the leadframe substrate 308a. The opening 316 may extend into and at least partially through, including completely through the antenna substrate 308b. If the opening 316 extends completely through the antenna substrate 308b, a resulting opening in the bottom of the antenna substrate 308b may be closed off as show in and described with respect to FIG. 2F (strip 232) or FIG. 2G (filling 234).

The mold mass 310a of the RFID chip module 310 may be inserted into the opening 316 of the antenna substrate 308b, and terminals (shown as two small ellipses) on its face up (top, as viewed) side of its leadframe portion 310b may be connected with ends of the antenna 320.

Then adhesive 314 may be applied, over the top (as viewed) surface of the antenna substrate 308b, and over the leadframe portion 310 b of the RFID chip module 310 to (i) join the antenna substrate 308b with the leadframe substrate 308a, and (ii) protect the connections of the antenna to the chip module. The leadframe substrate and antenna substrate may then be laminated together, using (for example) heat and pressure. Finally, a cover layer (not shown) may be disposed over the top (as viewed) of the leadframe substrate (i.e., the entire inlay substrate).

FIG. 3B is a cross-sectional view, illustrating a passport laminate, post lamination, comprising a leadframe substrate, an adhesive layer and an inlay substrate, wherein the adhesive layer covering the antenna interconnections to the leadframe side of the chip module in an opening of the leadframe substrate, according to an embodiment of the invention.

The overall thickness of the electronic laminate 200 in FIG. 3B may be approximately 360 μm. The adhesive layer stretches (extends) over the leadframe, protecting the interconnections, while at the same time is the medium which adhesively attaches the two substrates together, and also fixes the chip module in place.

After laminating the two substrates together, the connections of the antenna to the RFID chip module may be approximately at the top surface of the inlay substrate, and may be covered by a cover layer (not shown).

While the invention(s) has/have been described with respect to a limited number of embodiments, these should not be construed as limitations on the scope of the invention(s), but rather as examples of some of the embodiments. Those skilled in the art may envision other possible variations, modifications, and implementations that are also within the scope of the invention(s), and claims, based on the disclosure(s) set forth herein.

What is claimed is:

1. A laminate for a secure document, comprising:
an antenna substrate having an antenna and a first opening sized to receive a mold mass portion of an RFID chip module;
an leadframe substrate having a second opening sized to receive a leadframe portion of an RFID chip module;
wherein the second opening is aligned with the first opening;
the second opening extends through the leadframe substrate; and
the first opening extends into and at least partially through the antenna substrate;
further comprising an adhesive layer disposed between the inlay substrate and the antenna substrate;
wherein the adhesive protects interconnections between the RFID chip module and the antenna.

2. The laminate of claim 1, wherein:
the first opening extends completely through the antenna substrate.

3. The laminate of claim 1, wherein:
the first opening extends completely through the antenna substrate.

4. A secure document comprising the laminate of claim 1.

5. The secure document of claim 4, comprising:
a chip module disposed in the recess and connected with the antenna.

6. A method of making an inlay substrate for a secure document, comprising:
providing a first substrate having a first opening;
providing an antenna on the first substrate;
disposing an RFID chip module in the first opening;
connecting the antenna to the RFID chip module;
after performing the previous steps, applying an adhesive layer over the first substrate, antenna, the RFID chip module and connections of the antenna with the RFID chip module.

7. The method of claim 6, further comprising:
providing a second substrate having a second opening;
joining the second substrate to the first substrate, with the second opening aligned with the RFID chip module.

8. The method of claim 6, wherein the secure document is a passport.
